(19) United States
(12) Patent Application Publication
(10) Pub. No.: US 2012/0229633 A1
(43) Pub. Date: Sep. 13, 2012

(54) Security System and Method for Network Equipment Rack Having Camera

(76) Inventors: Thomas J Boucino, Mooresville, NC (US); Larry Ross, Princeton, TX (US); Darshan Patell, Plano, TX (US)

(21) Appl. No.: 13/414,750

(22) Filed: Mar. 8, 2012

Related U.S. Application Data
(60) Provisional application No. 61/451,341, filed on Mar. 10, 2011.

(51) Int. Cl. H04N 7/18; H05K 7/00

(52) U.S. Cl. 348/143; 361/679.02; 348/E07.085

(57) ABSTRACT

A network equipment rack includes a first support and a second support spaced from the first support by a given distance, the first and second supports configured to support a plurality of modules in a space between the supports and each support including a plurality of openings. At least one network module is mounted in the rack between the first support and the second support and may include a plurality of ports configured to receive a connector. A camera panel is also mounted in the rack between the first support and the second support and includes a panel member having a first end connected to the first support and a second end connected to the second support and an aperture through the panel member between the first end and the second end and a camera mounted in the aperture.

### CROSS-REFERENCE TO RELATED APPLICATIONS

The present application claims the benefit of U.S. Provisional Patent Application No. 61/451,341, filed Mar. 10, 2011, the entire contents of which are hereby incorporated by reference.

### FIELD OF THE INVENTION

The present invention is directed toward a network equipment rack associated with a camera and toward a method of providing security for equipment mounted in the rack, and, more specifically, toward a network equipment rack having a camera configured to monitor the vicinity of the rack and toward a method of capturing at least one image of persons attempting to access equipment mounted in the rack.

### BACKGROUND

Security is an important concern in data and communication centers and in other facilities that house computer and/or network and/or telecommunications equipment. Part of this security comprises software that monitors network use and file access and that determines what actions are being taken by various users of a network. The software may also control access to network resources via the use of passwords or other identifiers. However, the physical computers, routers, storage devices and cabling that interconnects these elements must also be protected to prevent unauthorized access to data or a network or system.

An additional layer of security may be provided by conventional access control technology that uses passwords, access cards and/or biometric information in order to limit physical access to secure areas. Conventional security cameras may also be used to monitor a data center or the entrances thereto. These conventional security arrangements are relatively effective in preventing unauthorized persons from entering a data or telecommunications center. However, they do little to prevent a person who is authorized to be in the secure facility from engaging in unauthorized activities. That is, once an individual is permitted to access the data and communications equipment in a facility, for maintenance purposes, for example, he may also be able to take other actions, accessing or copying or modifying protected data, for example, that are prohibited. Using conventional monitoring techniques, it may be difficult to determine which one of a group of persons authorized to be in a secure facility has impermissibly accessed or changed data.

One field that has established policies for data security is the payment card industry (PCI), and the PCI has developed a data security standard (DSS) to encourage and enhance cardholder data security and facilitate the broad adoption of consistent data security measures globally. There are twelve PCI DSS requirements within the standard, which are herein incorporated by reference. One of these requirements, Requirement 9.1.1, provides: “9.1.1 Use video cameras or other access control mechanisms to monitor individual physical access to sensitive areas. Review collected data and correlate with other entries. Store for at least three months, unless otherwise restricted by law. Note: ‘Sensitive areas’ refers to any data center, server room or any area that houses systems that store, process, or transmit cardholder data. This excludes the areas where only point-of-sale terminals are present, such as the cashier areas in a retail store.”

To comply with this section of the PCI DSS, a video camera and recording system should be in place to observe and monitor access to sensitive data center areas. The solution of the background art is to mount a standalone analogue camera system in the networking area. The standalone nature of camera system is similar to those used for security in a convenience store, wherein the video is stored on a DVR connected to the camera and the images are stored for the required time period before being overwritten. While such an arrangement may narrow down the list of persons who have accessed particular data when a security breach is found, it may be difficult to distinguish between authorized and unauthorized persons who performing actions at a given location. It would therefore be desirable to provide a method and device that make it easier to determine who is accessing or modifying a given piece of network, computer, data storage and/or telecommunications equipment.

### SUMMARY OF THE INVENTION

This and other problems are addressed by the present invention, a first aspect of which comprises a network equipment rack that includes a first support and a second support spaced from the first support by a given distance. The first and second supports are configured to support a plurality of network modules in a space therebetween. At least one module is mounted in the rack between the first and second supports, and a camera panel is mounted in the rack between supports. The camera panel includes a panel member having a first end connected to the first support and a second end connected to the second support and an aperture through the panel member between the first end and the second end and a camera mounted in the aperture.

Another aspect of the invention comprises a device comprising a rack having a first support and a second support spaced from the first support by a given distance, where the first and second supports are configured to support a plurality of network modules in a space therebetween. The device also includes a camera, and at least one network module is mounted in the rack between the first support and the second support. The at least one network module includes a plurality of ports, each port being configured to receive a connector, and the at least one network module is configured to generate a signal in response to a connector being added to or removed from one of the plurality of ports in the at least one network module. The camera is in communication with the at least one network module and is configured to capture at least one image in response to the signal.

A further aspect of the invention comprises a method that involves providing a rack, mounting at least one network module in the rack, the at least one network module including a plurality of ports, associating a camera with the rack, and capturing at least one image with the camera in response to a connector being inserted into or removed from one of the plurality of ports.

### BRIEF DESCRIPTION OF THE DRAWINGS

These and other aspects of the invention will be better appreciated after a reading of the following detailed description together with the attached drawings wherein:

FIG. 1 is a front elevational view of a network rack supporting network equipment and a camera panel according to a first embodiment of the present invention.

FIG. 2 is a perspective view of the network rack of FIG. 1 mounted in a cabinet having a door.

FIG. 3 is a front elevational view of the camera panel of FIG. 1.

FIG. 4 is a top plan view of the camera panel of FIG. 3.

FIG. 5 is front elevational view of a camera panel according to a second embodiment of the invention.

FIG. 6 is a perspective view of the camera panel of FIG. 5 with the camera removed to show elements of the panel.

### DETAILED DESCRIPTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

The phrase “network equipment” is intended to describe various types of computer and/or communications equipment of the type that may be mounted in a rack and used for sending and/or receiving data over a communications network. This phrase thus includes servers and related devices for storing or processing data, routers and switches, and communications modules of the type that allow for the interconnection of various electrical or optical cables or fibers.

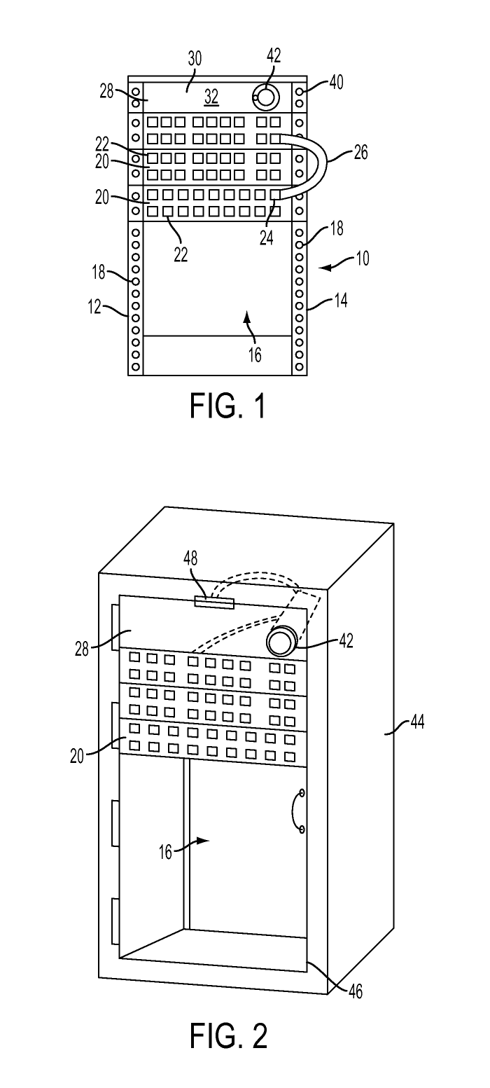

FIG. 1 illustrates a rack 10 comprising at least a first vertical support 12 and a second vertical support 14 spaced from the first vertical support 12 by a space 16 and where each of the first and second vertical supports 12, 14 includes a plurality of openings 18 for mounting equipment to the rack 10. A plurality of network modules 20 are mounted in the space 16 in the rack 10, and each of the modules includes a plurality of ports 22 configured to receive a connector 24, such as the connectors 24 on either end of patch cord 26. Only a single patch cord 26 is illustrated in FIG. 1; however, in use, a greater number of patch cords 26 will generally be present. While the first and second supports 12, 14 are described herein as being “vertical” and the modules 20 are illustrated in a horizontal orientation, the rack 10 could be used in an environment wherein the first and second supports 12 and 14 are horizontal and the modules 20 extend vertically.

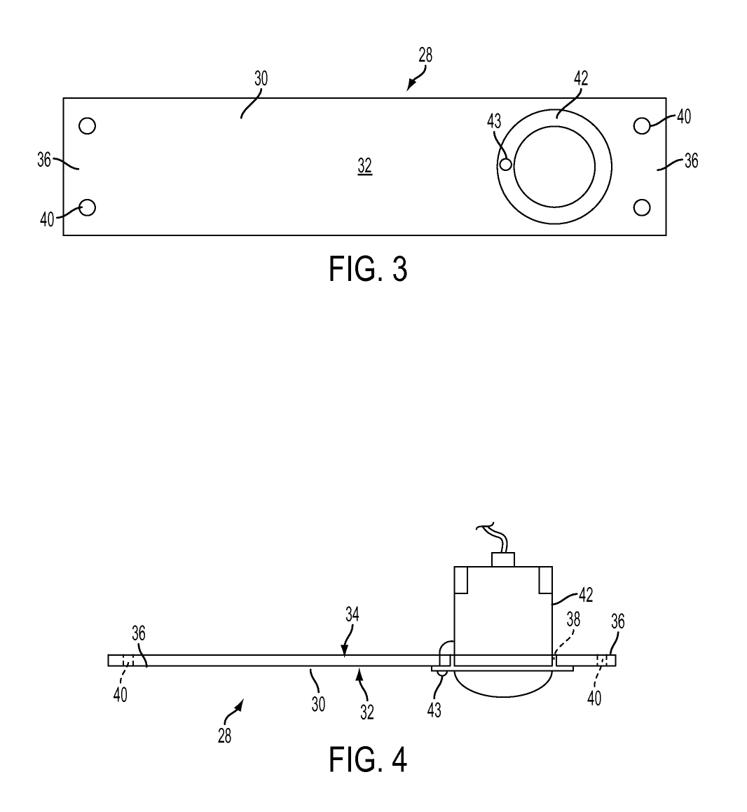

A camera panel 28, illustrated by itself in FIGS. 3 and 4, is also mounted in the rack 10, which camera panel 28 includes a panel member 30 having a front face 32, a rear face 34, and first and second sides 36. An aperture 38 extends through the panel member 30, and the panel member 30 further includes mounting holes 40 at the first and second sides 36 for mounting the camera panel 28 to the first and second supports 12, 14 of the rack 10. A camera 42 is mounted in the aperture 38, and because the camera panel 28 is mounted at approximately head level, it is well positioned to capture facial images of persons accessing the rack 10. If the camera panel 28 is mounted significantly higher or lower than head level, the camera 42 may be mounted at an angle so that it is aimed at the region where the face of a person accessing the modules 20 in the rack 10 would be expected to be found.

The camera 42 may comprise, for example, an internet protocol camera that is configured to send captured images and/or video to a storage device (not illustrated) that may be located in or near the rack 10 or remotely. A suitable camera is available from Axis Communications (http://www.axis.com) of Chelmsford, Mass., as model M3011, and the “Axis M3011 Network Camera User Manual” is hereby incorporated by reference. The camera 42 may be configured to capture one or more images, which may comprise individual still images or a video stream, upon the detection of motion or on receipt of a signal produced by various types of sensors in communication with the camera 42. Furthermore, the camera 42 may be configured to detect motion only immediately in front of the rack 10 so as to only capture images of persons close enough to the rack 10 to access the network modules 20 mounted therein. In this manner, a file can be provided that relates primarily to persons accessing a given rack 10, and the images may be time-stamped to provide a record of who accessed equipment on a given rack 10 and the time of the access. The camera 42 may optionally include a light source 43 that is actuated when the camera 42 is capturing images. Persons in front of camera 42 might instinctively look at the light source 43 when it turns on, and this helps ensure that a person will be facing the camera 42 when image capture begins.

The camera 42 may be actuated in response to signals other than those produced by a motion detector. For example, as illustrated in FIG. 2, the rack 10 may comprise or be mounted in a cabinet 44 that includes a door 46. Sensor elements 48 connected to the door 46 produce an output signal that is sent to the camera 42 each time the door 46 is opened. The camera 42 may be configured to capture an image each time the door 46 is opened or closed or to capture images or video for the entire period during which the door 46 is open.

Alternately or in addition, the network modules 20 may be of the type that output a signal each time a connector 24 is inserted into or removed from one of its ports 22. Such a system is sold by the assignee of the present application, CommScope, Inc. of North Carolina under the trademark “iPatch,” and a reference manual for the iPatch system entitled The Systimax iPatch System Panel Manager Guide, CommScope, Inc., June 2009, is incorporated herein by reference. The camera 42 may be connected to a suitable iPatch controller in order to capture an image, series of images or video each time a connector 24 is inserted or removed from one of the ports 22, and the captured images may be associated with other stored iPatch data such as information identifying a port that was accessed and the time of the access. In this manner, a record of the connection changes at the network modules 20 can be associated with images of the person making the changes in order to better determine whether a particular change was authorized. Beneficially, the camera 42 may be configured to record substantially continuously and then selectively overwrite images that are not needed. In this manner, when the iPatch system sends a signal to the camera 42 to indicate that a change has been made, the camera 42 may save images from several seconds before and several seconds after the change to increase the likelihood that a recognizable facial image of the person making the change is captured and not, merely, for example, an image of the top of a person's head when the person is looking down while adding or removing a patch cord 26.

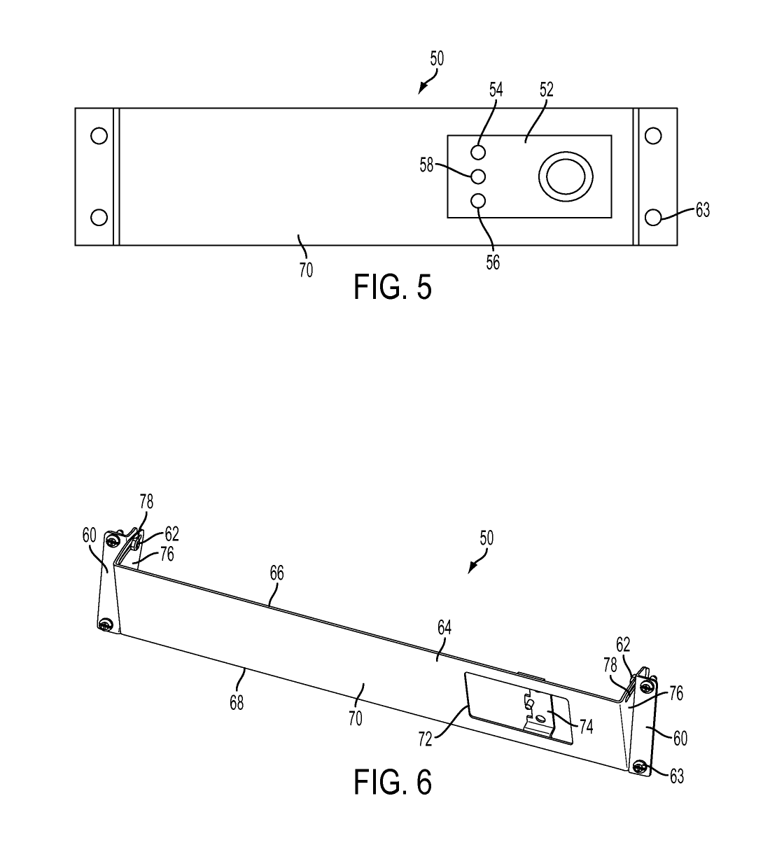

FIG. 5 illustrates a camera panel 50 with a camera 52 according to a second embodiment of the present invention. The camera 52 may be part of a module that includes features beyond image capture and may include, for example, a light source 54, a speaker 56 and a microphone 58. In addition to capturing images, a pre-recorded message stored in a memory (not illustrated) in the camera 52 could be triggered to audibly advise a person in front of the camera 52 that they are approaching a protected area and being monitored, or that an alert has been issued, or that a security code must be presented, etc. The same or a different message could be played when the door 46 to the cabinet 44 is opened or when the addition or removal of a patch cord 26 is detected.

The camera panel 50, illustrated without the camera 52 in FIG. 6, comprises first and second fixed support portions 60 each including a boss 62, which support portions 60 include openings 63 for mounting the camera panel 50 to the openings 18 on the first and second vertical supports 14, 16 of the rack 10. The camera panel 50 also includes a second, pivotable panel member 64 having a top edge 66, a bottom edge 68, and a central portion 70 having an aperture 72 and a bracket 74 on one side of the aperture 72 for securing the camera 52 in the panel member 64. First and second side walls 76 project from the central portion 70, and the panel member 64 is pivotably connected to the first and second fixed support portions 60 near the bottom of the side walls 76. Each side wall 72 includes an arcuate slot 78 near the top thereof. The bosses 62 on the fixed support portions 60 are received in the arcuate slots 78 of the side walls 76 to guide and limit the pivotable movement of the panel member 64 relative to the first and second fixed support portions 60 and the rack 10. In this manner, the plane of the panel member 64 can be angled with respect to the plane of the front of the rack 10 to facilitate aiming the camera 52 in a desired direction.

The camera 42 of the first embodiment could be mounted in a pivotable camera panel such as camera panel 50 or the camera 52 of the second embodiment could be mounted in a non-pivoting camera panel such as camera panel 28 of the first embodiment. Alternately, a camera could be mounted at a different location on a rack or mounted near a rack in a manner that still allows the capture of a facial image of a person making change to modules in the rack.

The present invention has been described herein in terms of several preferred embodiments. Modifications and additions to these embodiments will become apparent to persons of ordinary skill in the relevant art upon a reading of the foregoing disclosure. It is intended that all such modifications and additions comprise a part of the present invention to the extent they fall within the scope of the several claims appended hereto.

We claim:

1. A network equipment rack comprising:
a first support and a second support spaced from the first support by a given distance, the first and second supports configured to support a plurality of network modules in a space therebetween;
at least one network module mounted in the rack between the first support and the second support;
a camera panel mounted in the rack between the first support and the second support, the camera panel comprising a panel member having a first end connected to the first support and a second end connected to the second support; and
a camera mounted to the camera panel.

2. The network equipment rack of claim 1 wherein the at least one network module includes a plurality of ports and wherein each port is configured to receive a connector.

3. The network equipment rack of claim 2, wherein the camera and at least one network module are configured such that the camera captures one or more images in response to a connector being added to or removed from one of the plurality of ports in the at least one network module.

4. The network equipment rack of claim 2, wherein the at least one network module is configured to send a signal to the camera in response to a connector being added to or removed from one of the plurality of ports in the at least one network module and wherein the camera is configured to capture one or more images in response to the signal.

5. The network equipment rack of claim 4, wherein the camera includes a light source and wherein the light source is actuated in response to the signal.

6. The network equipment rack of claim 4, wherein the camera is configured to play an audio message in response to the signal.

7. The network equipment rack of claim 1 housed in a cabinet having a door.

8. The network equipment rack of claim 7, including a door sensor for producing door signal when the door is opened, said door sensor being configured to communicate the door signal to the camera, and said camera being configured to capture at least one image in response to the door signal.

9. The network equipment rack of claim 1, wherein the camera panel is mounted for pivoting movement relative to the first and second vertical supports.

10. The network equipment rack of claim 1, wherein the camera panel includes first portions fixedly mounted to the first and second supports and a second portion pivotably mounted to the first portion, and wherein the camera is mounted to the second portion.

11. The network equipment rack of claim 1, wherein the first and second supports each have a mounting surface including a plurality of mounting openings, wherein the mounting surfaces of the first and second supports each lie in a first plane, and wherein the camera panel lies in a second plane angled with respect to the first plane.

12. The network equipment rack of claim 1, wherein the camera panel comprises a 2U panel.

13. The network equipment rack of claim 1, wherein the camera panel has a width of 19 inches or 22 inches or 23 inches.

14. The network equipment rack of claim 2:
wherein the first and second supports are vertical and wherein the camera panel is mounted above the at least one network module;
wherein the at least one network module is configured to send a signal to the camera in response to a connector being added to or removed from one of the plurality of ports in the at least one network module and wherein the camera is configured to capture one or more images in response to the signal;
wherein the camera includes a housing fixedly mounted in an aperture in the camera panel, wherein the camera panel includes first portions fixedly mounted to the first and second supports and a second portion pivotably mounted on the first portion, and wherein the aperture is located in the second portion.

15. A device comprising:
a rack having a first support and a second support spaced from the first support by a given distance, the first and second supports configured to support a plurality of network modules in a space therebetween;
a camera; and
at least one network module mounted in the rack between the first support and the second support, the at least one network module including a plurality of ports, each port configured to receive a connector, the at least one network module configured to generate a signal in response to a connector being added to or removed from one of the plurality of ports in the at least one network module;
wherein the camera is in communication with the at least one network module and configured to capture at least one image in response to the signal.

16. The device of claim 15, wherein the rack includes a door and a door sensor for producing door signal when the door is opened, said door sensor being in communication with the camera, and said camera being configured to capture at least one image in response to receipt of the door signal.

17. The device of claim 16 wherein the camera is mounted in an aperture in a camera panel and the camera panel is mounted to the first and second supports.

18. The device of claim 17, wherein the camera panel is pivotable relative to the first and second supports.

19. A method comprising:
providing a network equipment rack;
mounting at least one network module in the rack, the at least one network module including a plurality of ports;
associating a camera with the rack; and
capturing at least one image with the camera in response to a connector being inserted into or removed from one of the plurality of ports.

20. The method of claim 19 wherein the rack comprises first and second spaced supports and wherein associating a camera with the rack comprises mounting a camera in an aperture in a panel and mounting the panel to the first and second spaced supports.
